(19) United States
(12) Patent Application Publication
(10) Pub. No.: US 2025/0342287 A1
(43) Pub. Date: Nov. 6, 2025

(54) AUTOMATED SIMULATION ANALYSIS: QUANTIFYING USER RESPONSE TO UI/UX TRANSFORMATIONS FOR IMPROVED APPLICATION ENGAGEMENT

(71) Applicant: Dell Products L.P., Round Rock, TX (US)

(72) Inventors: Abhishek Mishra, Bangalore (IN); Vivek Bhargava, Bangalore (IN); David Sydow, Merrimack, NH (US); Dev Kathuria, Greater Noida (IN)

(73) Assignee: Dell Products L.P., Round Rock, TX (US)

(21) Appl. No.: 18/653,019

(22) Filed: May 2, 2024

(51) Int. Cl. G06F 30/20

(52) U.S. Cl. CPC G06F 30/20

(57) ABSTRACT

Methods, system, and non-transitory processor-readable storage medium for a simulation analysis system are provided herein. An example method includes monitoring, by a simulation analysis system, user interactions with User Interface (UI) elements on a user interface to obtain click patterns associated with the UI elements. The simulation analysis system generates simulated user profiles based on the user interactions. The simulation analysis system calculates a User Interface/User Experience (UI/UX) impact using the click patterns associated with the simulated user profiles, and identifies a set of high impact UI elements associated with the UI.

### FIELD

The field relates generally to analyzing the impact of modifications to a user interface, and more particularly to a simulated analysis of the impact of modifications to user interface elements in the user interface in information processing systems.

### BACKGROUND

User interface and user experience play a pivotal role in shaping user engagement, adoption rates, and competitive advantage in today's digital landscape. Therefore, it is critical to understand the impact of a given user interface/user experience change within the context of a systems active user-base.

### SUMMARY

Illustrative embodiments provide techniques for implementing a simulation analysis system in a storage system. For example, illustrative embodiments provide a simulation analysis system that monitors user interactions with User Interface (UI) elements on a user interface to obtain click patterns associated with the UI elements. The simulation analysis system generates simulated user profiles based on the user interactions, and calculates a User Interface/User Experience (UI/UX) impact using the click patterns associated with the simulated user profiles. The simulation analysis system identifies a set of high impact UI elements associated with the UI. Other types of processing devices can be used in other embodiments. These and other illustrative embodiments include, without limitation, apparatus, systems, methods and processor-readable storage media.

### BRIEF DESCRIPTION OF THE DRAWINGS

FIG. 1 shows an information processing system including a simulation analysis system in an illustrative embodiment.

FIG. 2 shows a flow diagram of a process for a simulation analysis system in an illustrative embodiment.

FIG. 3 shows a simulation analysis system in an illustrative embodiment.

FIG. 4 illustrates the button labeling performed by the simulation analysis system in an illustrative embodiment.

FIG. 5 illustrates an example scroll heatmap in an illustrative embodiment.

FIGS. 6 and 7 show examples of processing platforms that may be utilized to implement at least a portion of the simulation analysis system embodiments.

### DETAILED DESCRIPTION

Illustrative embodiments will be described herein with reference to exemplary computer networks and associated computers, servers, network devices or other types of processing devices. It is to be appreciated, however, that these and other embodiments are not restricted to use with the particular illustrative network and device configurations shown. Accordingly, the term “computer network” as used herein is intended to be broadly construed, so as to encompass, for example, any system comprising multiple networked processing devices.

Described below is a technique for use in implementing a simulation analysis system, which technique may be used to provide, among other things a simulated analysis of the impact of modifications to UI elements in a user interface. The simulation analysis system monitors user interactions with User Interface (UI) elements on a user interface to obtain click patterns associated with the UI elements. The simulation analysis system generates simulated user profiles based on the user interactions, and calculates a User Interface/User Experience (UI/UX) impact using the click patterns associated with the simulated user profiles. The simulation analysis system identifies a set of high impact UI elements associated with the UI. Other types of processing devices can be used in other embodiments.

The current state of the art for the evaluation of UI/UX changes relies on long running and expensive user testing sessions. Typically, user experience engineers coordinate multiple users and have them perform a series of tasks to evaluate the efficacy of a UI/UX screen. It is not feasible, however, to create a session for every UI/UX change that is implemented.

A minor user interface change might seem insignificant. If a core service, like the purchasing or “add to cart” functionalities are altered, even a change that benefits 80% of the users may have significant repercussions. For example, if a website with 1 million regular users implements a change that negatively impacts 20% of its users, this may lead to 200,000 potentially dissatisfied customers, and this may lead to substantial business losses.

Conventional technologies fail to evaluate the impact of modification of UI elements in a user interface. Conventional technologies fail to provide a cost-effective and controlled environment to evaluate the effectiveness of UI/UX modifications before implementation. Conventional technologies fail to provide a projected customer impact of changing existing elements within a user interface. Conventional technologies fail to provide a report of high impact UI elements in the context of a website or user interface. Conventional technologies fail to evaluate the impact of modification of UI elements using clickstream monitoring software. Conventional technologies fail to assess the projected customer impact based on simulated user profiles built using digital footprints captured from users. Conventional technologies fail to leverage simulated user testing based on digital footprints.

By contrast, in at least some implementations in accordance with the current technique as described herein, a simulation analysis system monitors user interactions with User Interface (UI) elements on a user interface to obtain click patterns associated with the UI elements. The simulation analysis system generates simulated user profiles based on the user interactions, and calculates a User Interface/User Experience (UI/UX) impact using the click patterns associated with the simulated user profiles. The simulation analysis system identifies a set of high impact UI elements associated with the UI.

Thus, a goal of the current technique is to provide a method and a system for a simulation analysis system that provides a cost-effective and controlled environment to evaluate the effectiveness of UI/UX modifications before implementation. Another goal is to measure the impact of UI/UX changes by leveraging simulated user testing and real digital footprints. Another goal is to assess the potential positive change in application usage experience, increase adoption and competitive edge resulting from UI/UX modifications. Yet another goal is to guide practitioners and organizations in making informed design decisions that positively impact user engagement, adoption rates, and overall user satisfaction.

In at least some implementations in accordance with the current technique described herein, the use of a simulation analysis system can provide one or more of the following advantages: evaluate the impact of modification of UI elements in a user interface, provide a cost-effective and controlled environment to evaluate the effectiveness of UI/UX modifications before implementation, provide a projected customer impact of changing existing elements within a user interface, provide a report of high impact UI elements in the context of a website or user interface, evaluate the impact of modification of UI elements using clickstream monitoring software, assess the projected customer impact based on simulated user profiles built using digital footprints captured from users, and leverage simulated user testing based on digital footprints.

In contrast to conventional technologies, in at least some implementations in accordance with the current technique as described herein, a simulation analysis system monitors user interactions with User Interface (UI) elements on a user interface to obtain click patterns associated with the UI elements. The simulation analysis system generates simulated user profiles based on the user interactions, and calculates a User Interface/User Experience (UI/UX) impact using the click patterns associated with the simulated user profiles. The simulation analysis system identifies a set of high impact UI elements associated with the UI.

In an example embodiment of the current technique, the simulation analysis system captures clickstream parameters using a website analytics system, where the clickstream parameters are associated with the user interactions.

In an example embodiment of the current technique, the simulation analysis system captures a click location representing a location in a user interface where a user clicked during a clickstream session, and captures a scroll location representing a time value associated with the user clicking on the user interface at the location.

In an example embodiment of the current technique, the website analytics system determines a beginning point and an ending point associated with the clickstream session.

In an example embodiment of the current technique, the simulation analysis system generates a simulated user from the clickstream session.

In an example embodiment of the current technique, the simulation analysis system translates the click location into at least one of a button and a clickable link in the user interface.

In an example embodiment of the current technique, the simulation analysis system creates a user profile associated with a simulated user, where the user profile represents at least one of demographics, behavior patterns and user preferences.

In an example embodiment of the current technique, the simulation analysis system determines a button relative weight using button location data, where the button location data represents a location in the user interface where a user clicked during a clickstream session.

In an example embodiment of the current technique, the button relative weight is a sum of clicks associated with the button location data associated with a plurality of clickstream sessions, divided by a sum of clicks associated with a plurality of button location data associated with the plurality of clickstream sessions, where each of the plurality of button location data represents a unique location in the user interface where the user clicked during a clickstream session.

In an example embodiment of the current technique, the simulation analysis system determines a scroll location weight using the button relative weight.

In an example embodiment of the current technique, the scroll location weight is the button relative weight multiplied by a scroll location percent associated with a scroll location, where the scroll location percent represents a percentage of users who have scrolled to the scroll location.

In an example embodiment of the current technique, a scroll location heatmap system provides the scroll location percent.

In an example embodiment of the current technique, the simulation analysis system determines a button depth weight using a button relative weight.

In an example embodiment of the current technique, the simulation analysis system determines the button depth weight by dividing the button relative weight by prior button clicks representing how many buttons were clicked and how many URL links were clicked before the button associated with the button depth weight was clicked within a clickstream session.

In an example embodiment of the current technique, the simulation analysis system determines a clickstream summation for each button in a clickstream session by summing a button dept weight and a scroll location weight associated with each button in the clickstream session.

In an example embodiment of the current technique, the simulation analysis system determines a button summation across a plurality of clickstream sessions for each button in the plurality of clickstream sessions, where the button summation is determined using the clickstream summation.

In an example embodiment of the current technique, the simulation analysis system calculates a standard deviation of the button summation across the plurality of clickstream sessions for each button in the plurality of clickstream sessions and identifies the UI/UX impact for each button in the plurality of clickstream sessions based on the standard deviation.

In an example embodiment of the current technique, the simulation analysis system, in response to selection of one of the UI elements in the UI, provides an impact assessment associated with modifying the one of the UI elements.

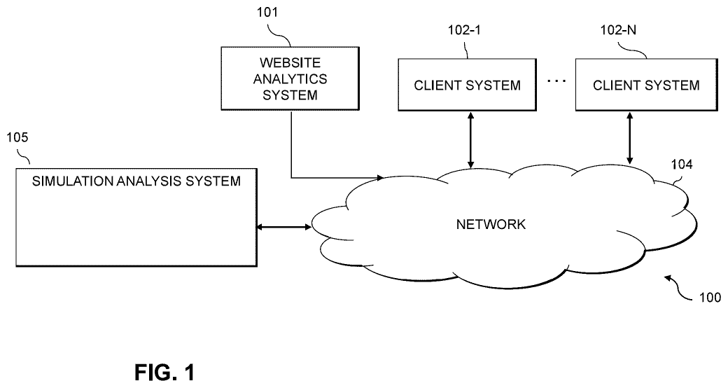

FIG. 1 shows a computer network (also referred to herein as an information processing system) 100 configured in accordance with an illustrative embodiment. The computer network 100 comprises a website analytics system 101, simulation analysis system 105, and client systems 102-N. The website analytics system 101, simulation analysis system 105, and client systems 102-N are coupled to a network 104, where the network 104 in this embodiment is assumed to represent a sub-network or other related portion of the larger computer network 100. Accordingly, elements 100 and 104 are both referred to herein as examples of “networks,” but the latter is assumed to be a component of the former in the context of the FIG. 1 embodiment. The simulation analysis system 105 may reside on a storage system. Such storage systems can comprise any of a variety of different types of storage including network-attached storage (NAS), storage area networks (SANs), direct-attached storage (DAS) and distributed DAS, as well as combinations of these and other storage types, including software-defined storage.

Each of the client systems 102-N may comprise, for example, servers and/or portions of one or more server systems, as well as devices such as mobile telephones, laptop computers, tablet computers, desktop computers or other types of computing devices. Such devices are examples of what are more generally referred to herein as “processing devices.” Some of these processing devices are also generally referred to herein as “computers.”

The client systems 102-N in some embodiments comprise respective computers associated with a particular company, organization or other enterprise. In addition, at least portions of the computer network 100 may also be referred to herein as collectively comprising an “enterprise network.” Numerous other operating scenarios involving a wide variety of different types and arrangements of processing devices and networks are possible, as will be appreciated by those skilled in the art.

Also, it is to be appreciated that the term “user” in this context and elsewhere herein is intended to be broadly construed so as to encompass, for example, human, hardware, software or firmware entities, as well as various combinations of such entities.

The network 104 is assumed to comprise a portion of a global computer network such as the Internet, although other types of networks can be part of the computer network 100, including a wide area network (WAN), a local area network (LAN), a satellite network, a telephone or cable network, a cellular network, a wireless network such as a Wi-Fi or WiMAX network, or various portions or combinations of these and other types of networks. The computer network 100 in some embodiments therefore comprises combinations of multiple different types of networks, each comprising processing devices configured to communicate using internet protocol (IP) or other related communication protocols.

Also associated with the simulation analysis system 105 are one or more input-output devices, which illustratively comprise keyboards, displays or other types of input-output devices in any combination. Such input-output devices can be used, for example, to support one or more user interfaces to the simulation analysis system 105, as well as to support communication between the simulation analysis system 105 and other related systems and devices not explicitly shown. For example, a dashboard may be provided for a user to view a progression of the execution of the simulation analysis system 105. One or more input-output devices may also be associated with any of the client systems 102-N.

Additionally, the simulation analysis system 105 in the FIG. 1 embodiment is assumed to be implemented using at least one processing device. Each such processing device generally comprises at least one processor and an associated memory, and implements one or more functional modules for controlling certain features of the simulation analysis system 105.

More particularly, the simulation analysis system 105 in this embodiment can comprise a processor coupled to a memory and a network interface.

The processor illustratively comprises a microprocessor, a microcontroller, an application-specific integrated circuit (ASIC), a field-programmable gate array (FPGA) or other type of processing circuitry, as well as portions or combinations of such circuitry elements.

The memory illustratively comprises random access memory (RAM), read-only memory (ROM) or other types of memory, in any combination. The memory and other memories disclosed herein may be viewed as examples of what are more generally referred to as “processor-readable storage media” storing executable computer program code or other types of software programs.

One or more embodiments include articles of manufacture, such as computer-readable storage media. Examples of an article of manufacture include, without limitation, a storage device such as a storage disk, a storage array or an integrated circuit containing memory, as well as a wide variety of other types of computer program products. The term “article of manufacture” as used herein should be understood to exclude transitory, propagating signals. These and other references to “disks” herein are intended to refer generally to storage devices, including solid-state drives (SSDs), and should therefore not be viewed as limited in any way to spinning magnetic media.

The network interface allows the simulation analysis system 105 to communicate over the network 104 with the website analytics system 101, and client systems 102-N and illustratively comprises one or more conventional transceivers.

A simulation analysis system 105 may be implemented at least in part in the form of software that is stored in memory and executed by a processor, and may reside in any processing device. The simulation analysis system 105 may be a standalone plugin that may be included within a processing device.

It is to be understood that the particular set of elements shown in FIG. 1 for simulation analysis system 105 involving the website analytics system 101, and client systems 102-N of computer network 100 is presented by way of illustrative example only, and in other embodiments additional or alternative elements may be used. Thus, another embodiment includes additional or alternative systems, devices and other network entities, as well as different arrangements of modules and other components. For example, in at least one embodiment, one or more of the simulation analysis system 105 can be on and/or part of the same processing platform.

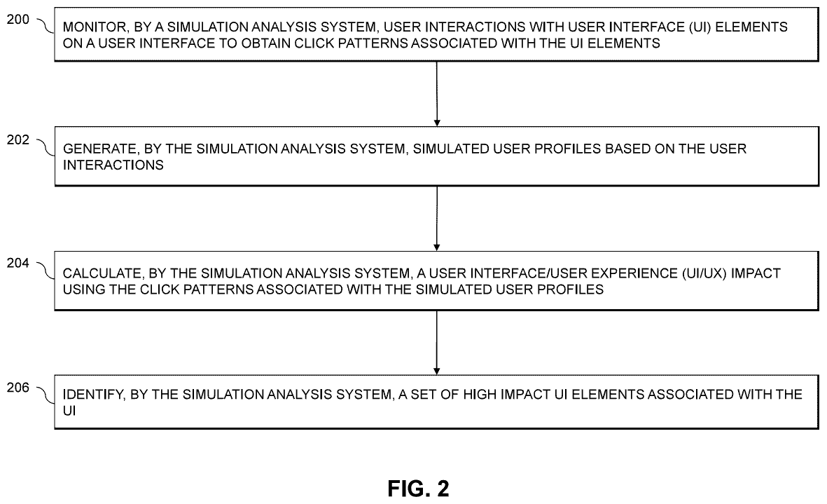

FIG. 2 is a flow diagram of a process for execution of the simulation analysis system 105 in an illustrative embodiment. It is to be understood that this particular process is only an example, and additional or alternative processes can be carried out in other embodiments.

At 200, the simulation analysis system 105 monitors user interactions with User Interface (UI) elements on a user interface to obtain click patterns associated with the UI elements. In an example embodiment, the user interface is a website, and the user is interacting with the website (i.e., scrolling on the website, clicking buttons, following uniform resource locator (URL), etc.). For example, the user may be interacting with the user interface on a client system 102-1. In an example embodiment, the UI may also be a Java based user interface.

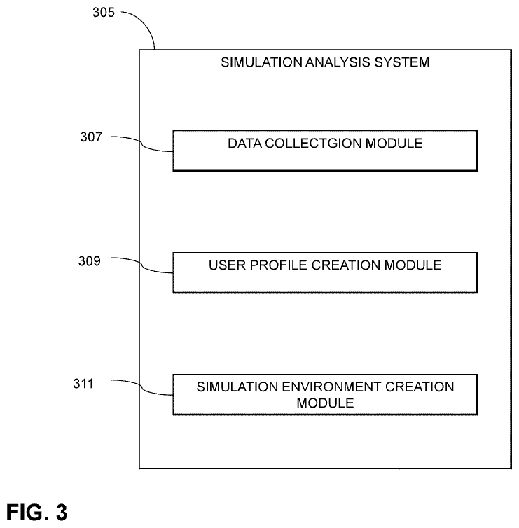

FIG. 3 shows a simulation analysis system 105 in an illustrative embodiment. The simulation analysis system 105 comprises a data collection module 307, a user profile creation module 309, and a simulation environment creation module 311. In an example embodiment, the data collection module 307 performs data preparation based on user research by collecting digital footprints captured from actual users interacting with the user interfaces. The data collection module 307 collects additional details such as user analytics, application usage data, user preferences, survey results, etc. The user profile creation module 309 creates simulated user profiles based on the digital footprints. The user profiles are each associated with a simulated user. A user profile represents at least one of the demographics, behavior patterns, and preferences associated with the user interacting with the user interfaces.

In an example embodiment, the data collection module 307 captures clickstream parameters using a website analytics system 101, where the clickstream parameters are associated with the user interactions (i.e., scrolling on the website, clicking buttons, following URLs, etc.). In an example embodiment, the website analytics system 101 may be a third-party application, such as Smartlook, Hotjar, etc.

In an example embodiment, the clickstream parameters captured by the data collection module 307 are used to determine where in the user interface the user clicked, and how far into the current clickstream session each click occurred. In an example embodiment, the website analytics system 101 determines the boundaries of the clickstream session, (for example, a beginning point and an ending point associated with each clickstream session). In an example embodiment, the clickstream parameters comprise capturing a click location representing a location in a user interface where a user clicked during a clickstream session. In another example embodiment, the clickstream parameters comprise capturing a scroll location representing a time value (such as a time stamp) associated with the user clicking on the user interface at the location.

At 202, the user profile creation module 309 generates simulated user profiles based on the user interactions. In an example embodiment, the user profile creation module 309 creates simulated user profiles by first generating simulated users. In an example embodiment, the simulated users are created by the user profile creation module 309 by consuming the clickstream information captured by the data collection module 307.

In an example embodiment, each user profile comprises a single clickstream session. The information associated with each user profile comprises a time series of data ordered chronologically from the start of the clickstream session, and each point in the time series comprises click location and scroll location as described below.

| Data | Calculation | Units |
|---|---|---|
| Click Location | Taken from data collection | x/y coordinates |
| Scroll Location | | Seconds |

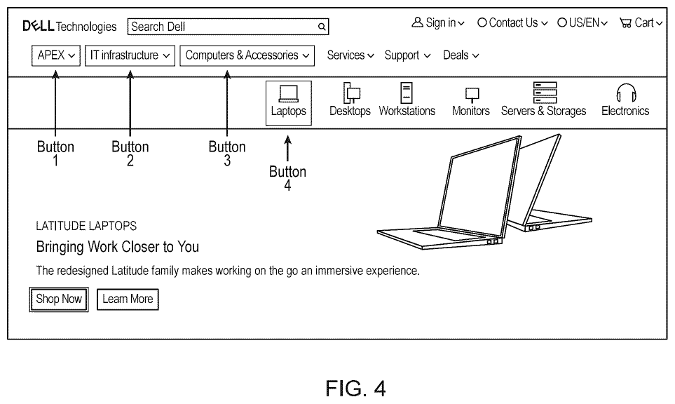

In an example embodiment, the simulation analysis system 105 performs button labeling by translating the click location into at least one of a button and a clickable link in the user interface. In other words, the click location is translated into individual buttons and/or clickable URL links on the user interface/webpage. FIG. 4 illustrates the button labeling performed by the simulation analysis system 105. In an example embodiment, user clicks that occurred within the user interface that did not occur on a button (or a link) are ignored.

At 204, the simulation analysis system 105 calculates a User Interface/User Experience (UI/UX) impact using the click patterns associated with the simulated user profiles. In an example embodiment, the simulation environment creation module 311 prepares a simulated environment that mimics the actual environment. The simulated environment comprises at least one of the following characteristics, a real replication of the interface, interactivity, controlled testing, data tracking and monitoring, scalability and flexibility for iterations, and integration with an analytics tool. The impact of modifications to the simulation environment are determined by comparing the user interface screens that are under test to be compared against the existing click patterns of each simulated user profile, and also comparing it to a customer impact algorithm.

Each button and/or link in a clickstream is given a relative weight based on the prior steps in the clickstream session. The relative weight is the overall number of clicks for a particular button across all recorded clickstreams. Thus, buttons that are clicked more frequently are weighted higher than other buttons, even if those higher weighted buttons are not frequently scrolled over, or are lower in the hierarchy of button clicks. In an example embodiment, the simulation analysis system 105 determines a button relative weight using button location data, where the button location data represents a location in the user interface where a user clicked during a clickstream session. In an example embodiment, the button relative weight is the sum of clicks associated with the button location data associated with a plurality of clickstream sessions, divided by a sum of clicks associated with a plurality of button location data associated with the plurality of clickstream sessions. Each of the plurality of button location data represents a unique location in the user interface where the user clicked during a clickstream session. In an example embodiment, the calculation of the button relative weight, B_{weight}, is illustrated below, given Bₘₐₓ unique buttons across all the click streams.

$${B}_{weight} = \frac{Sum of clicks on {B}_{n} across all streams}{Sum of clicks on {B}_{1} ... {B}_{max} across all streams}$$

In an example embodiment, the simulation analysis system 105 determines a scroll location weight using the button relative weight. Each button/link is assigned a scroll location weight based on its location in the user interface. The scroll location weight is the button relative weight multiplied by a scroll location percent associated with a scroll location, where the scroll location percent represents a percentage of users who have scrolled to the scroll location. In an example embodiment, a scroll location heatmap system provides the scroll location percent.

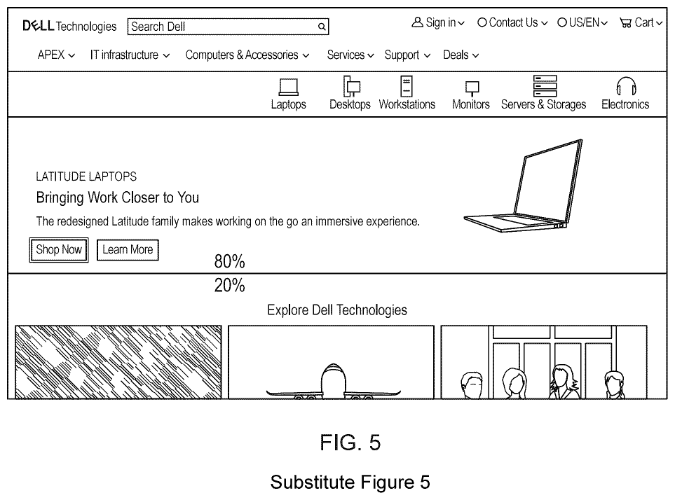

Scroll location heatmaps provide information on how far users scroll on each user interface webpage before navigating away from it. FIG. 5 illustrates an example scroll heatmap where 80% of the users have scrolled above the line, and only 20% of the users have scrolled below the line.

In other words, for a given button/link weight Bₙ, its relative weight is multiplied by its scroll location percentage in a scroll heatmap. This calculation skews impact results to create a higher impact report for buttons and links that are viewed by more users. The scroll location percentage is the percentage of website visitors who have scrolled to the location (identified by the scroll location heatmap). The scroll location weight, B_{scroll}, given a button/link B_{weight} is determined as illustrated below.

$${B}_{Scroll} = {B}_{weight} * scroll\_location \_percent$$

In an example embodiment, the simulation analysis system 105 determines a button depth weight using a button relative weight. The button depth weight is determined by dividing the button relative weight by prior button clicks representing how many buttons were clicked and how many URL links were clicked before the button associated with the button depth weight was clicked within a clickstream session. Each button/link is assigned a button depth weight, based on how many unique button and link clicks occurred prior to the clicking of that particular button/link. For the relative weight of a given button/link B_{weight}, its depth weight is divided by the number of buttons clicked prior to this button/link. This skews impact results to ensure that the first buttons in a hierarchy of clicks are weighted with more importance. In an example embodiment, if the clickstream data for button/link B₃ includes a click on button B₁ and button B₂, the weight of the B₃ button/link is divided by 2. The button/link depth weight, B_{depth}, is determined as illustrated below.

$${B}_{depth} = \frac{{B}_{weight}}{Number of Prior Button Clicks}$$

At 206, the simulation analysis system 105 identifies a set of high impact UI elements associated with the UI. In an example embodiment, the simulation analysis system 105 calculates the UI/UX impact by determining a clickstream summation, a like button/link summation, and impact labeling. The simulation analysis system 105 determines a clickstream summation for each button in a clickstream session by summing a button dept weight and a scroll location weight associated with each button in the clickstream session. In other words, the simulation analysis system 105 creates a sum of the button/link depth weight and the scroll location weight for each button click across each individual clickstream.

In an example embodiment, the simulation analysis system 105 determines like button/link summation across a plurality of clickstream sessions for each button in the plurality of clickstream sessions, where the button summation is determined using the clickstream summation. In other words, the button/link in each clickstream is summed with the calculated weights for the same button/link in other clickstreams. The weights from this calculation are stored in an ordered list.

In an example embodiment, the simulation analysis system 105 calculates a standard deviation of the button summation across the plurality of clickstream sessions for each button in the plurality of clickstream sessions, and identifies the UI/UX impact for each button in the plurality of clickstream sessions based on the standard deviation. The simulation analysis system 105 labels the UI/UX impact by taking the standard deviation of the weight for each button/link calculated for the like button/link summation. The buttons/links that are outliers for more than a positive standard deviation from the mean are labeled as high impact. The buttons/links that are below a standard deviation from the mean are labeled as minimal impact. The standard deviation-based impact labeling ensures that, in cases where a single, high-use button is changed, the simulation analysis system 105 provides an impact report of high impact. Alternatively, in the scenarios where many buttons are changed, the impact of a single button change will be minimized.

In an example embodiment, in response to selection of one of the UI elements in the UI, the simulation analysis system 105 provides an impact assessment associated with modifying the one of the UI elements. For example, a user interface designer who is modifying UI elements in a simulated environment, such as that created by the simulation environment module 311, may utilize the simulation analysis system 105 to determine the impact on modifying a particular UI element, or a plurality of UI elements. This enables the user interface designers and their associated organizations to make informed decisions regarding UI/UX changes, enhances the usage experience of user interfaces, increases adoption rates, and allows organizations to have a competitive edge in the market.

For example, the simulation analysis system 105 provides an impact report for UI elements (i.e., a set of buttons/links) in an interface with the parameters outlined below. In an example embodiment, the sample button data is illustrated below.

| Button/Link ID | Scroll Location |
|---|---|
| B1 | 10% |
| B2 | 80% |
| B3 | 60% |
| B4 | 70% |
| B5 | 90% |

The sample clickstream data is illustrated below.

| ClickstreamID | Action 1 | Action 2 | Action 3 |
|---|---|---|---|
| 1 | B2 | B1 | |
| 2 | B2 | B3 | B4 |
| 3 | B2 | B1 | B3 |
| 4 | B5 | B3 | |
| 5 | B5 | | |
| 6 | B2 | B3 | B1 |

The simulation analysis system 105 calculates the button relative weight, the scroll weight, and the depth weight as illustrated below.

| Button/Link ID | Relative Weight | Scroll Weight | Depth Weight | |
|---|---|---|---|---|
| B1 | 3/15 (.2) | .2 * .1 = .02 | .2/4 | (.05) |
| B2 | 4/15 (.27) | .27 * .8 = .21 | .27/1 | (.27) |
| B3 | 4/15 (.27) | .27 * .6 = .16 | .27/4 | (.07) |
| B4 | 1/15 (.07) | .07*.7 = .05 | .07/2 | (.035) |
| B5 | 2/15 (.13) | .13 * .9 = .112 | .13/1 | (.13) |

The simulation analysis system 105 determines the button summation as illustrated below.

| Button ID | Button Summation |
|---|---|
| B1 | (.05 + .02) * 3 = .21 |
| B2 | (.21 + .27) * 4 = 1.92 |
| B3 | (.16 + .07) * 4 = .92 |
| B4 | (.05 + .035) * 1 = .085 |
| B5 | (.112 + .13 ) *2 = .484 |

The simulation analysis system 105 then calculates the standard deviation. In the calculation illustrated below, there are 5 buttons, thus n=5, and Bᵢ is the button summation illustrated above, where B is the mean value of the data set. The simulation analysis system 105 calculates the mean and standard deviation based on the values determined for each button summation associated with each button.

$$Standard Deviation = \sqrt{\frac{{\sum }_{i = 1}^{n} {( {B}_{i} - \overline{B} )}^{2}}{n - 1}}$$

$$\overline{B} = \frac{\text{.21} + 19.2 + \text{.92} + \text{.085} + \text{.284}}{5} = \frac{3.599}{5} = \text{.7198}$$

$${\sum }_{i = 1}^{n} {( {B}_{i} - \overline{B} )}^{2} = \text{.26} + 1.44 + \text{.04} + \text{.4} + \text{.06} = 2.2$$

$$\sqrt{\frac{2.2}{4}} = \text{.741}$$

In an example embodiment, the simulation analysis system 105 provides an impact report for each of the 5 buttons in the example illustrated above, based on the calculated deviation. In the example below, button B₂ has a high impact since it is more than one standard deviation from the mean. As illustrated in the sample clickstream data shown above, B₂ is the first click for 4 of the 6 click streams, and there are subsequent clicks underneath it as well in each click stream.

| Button ID | Deviation From Mean | High Impact |
|---|---|---|
| B1 | \| .21 − .7198 \| = .5098 | No |
| B2 | \| 1.92 − .7198 \| = 1.2002 | Yes |
| B3 | \| .92 − .7198 \| = .2002 | No |
| B4 | \| .085 − .7198 \| = .6348 | No |
| B5 | \| .484 − .7198\| = .2358 | No |

Accordingly, the particular processing operations and other functionality described in conjunction with the flow diagram of FIG. 2 are presented by way of illustrative example only, and should not be construed as limiting the scope of the disclosure in any way. For example, the ordering of the process steps may be varied in other embodiments, or certain steps may be performed concurrently with one another rather than serially.

The above-described illustrative embodiments provide significant advantages relative to conventional approaches. For example, some embodiments are configured to measure the impact of UI/UX changes by leveraging simulated user testing and real digital footprints. These and other embodiments guide practitioners and organizations in making informed design decisions that positively impact user engagement, adoption rates, and overall user satisfaction. Embodiments disclosed herein assess the potential positive change in application usage experience, increased adoption, and competitive edge resulting from UI/UX modifications. Embodiments disclosed herein provide a cost-effective and controlled environment to evaluate the effectiveness of UI/UX modifications before implementation. Embodiments disclosed herein provide a report of high impact UI elements in the context of a website or user interface. Embodiments disclosed herein leverage simulated user testing based on digital footprints.

It is to be appreciated that the particular advantages described above and elsewhere herein are associated with particular illustrative embodiments and need not be present in other embodiments. Also, the particular types of information processing system features and functionality as illustrated in the drawings and described above are exemplary only, and numerous other arrangements may be used in other embodiments.

As mentioned previously, at least portions of the information processing system 100 can be implemented using one or more processing platforms. A given such processing platform comprises at least one processing device comprising a processor coupled to a memory. The processor and memory in some embodiments comprise respective processor and memory elements of a virtual machine or container provided using one or more underlying physical machines. The term “processing device” as used herein is intended to be broadly construed so as to encompass a wide variety of different arrangements of physical processors, memories and other device components as well as virtual instances of such components. For example, a “processing device” in some embodiments can comprise or be executed across one or more virtual processors. Processing devices can therefore be physical or virtual and can be executed across one or more physical or virtual processors. It should also be noted that a given virtual device can be mapped to a portion of a physical one.

Some illustrative embodiments of a processing platform used to implement at least a portion of an information processing system comprises cloud infrastructure including virtual machines implemented using a hypervisor that runs on physical infrastructure. The cloud infrastructure further comprises sets of applications running on respective ones of the virtual machines under the control of the hypervisor. It is also possible to use multiple hypervisors each providing a set of virtual machines using at least one underlying physical machine. Different sets of virtual machines provided by one or more hypervisors may be utilized in configuring multiple instances of various components of the system.

These and other types of cloud infrastructure can be used to provide what is also referred to herein as a multi-tenant environment. One or more system components, or portions thereof, are illustratively implemented for use by tenants of such a multi-tenant environment.

As mentioned previously, cloud infrastructure as disclosed herein can include cloud-based systems. Virtual machines provided in such systems can be used to implement at least portions of a computer system in illustrative embodiments.

In some embodiments, the cloud infrastructure additionally or alternatively comprises a plurality of containers implemented using container host devices. For example, as detailed herein, a given container of cloud infrastructure illustratively comprises a Docker container or other type of Linux Container (LXC). The containers are run on virtual machines in a multi-tenant environment, although other arrangements are possible. The containers are utilized to implement a variety of different types of functionality within the information processing system 100. For example, containers can be used to implement respective processing devices providing compute and/or storage services of a cloud-based system. Again, containers may be used in combination with other virtualization infrastructure such as virtual machines implemented using a hypervisor.

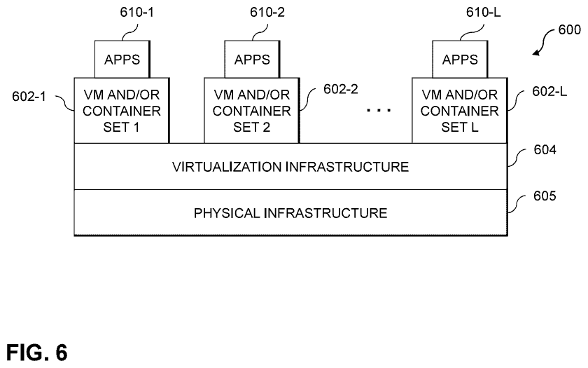

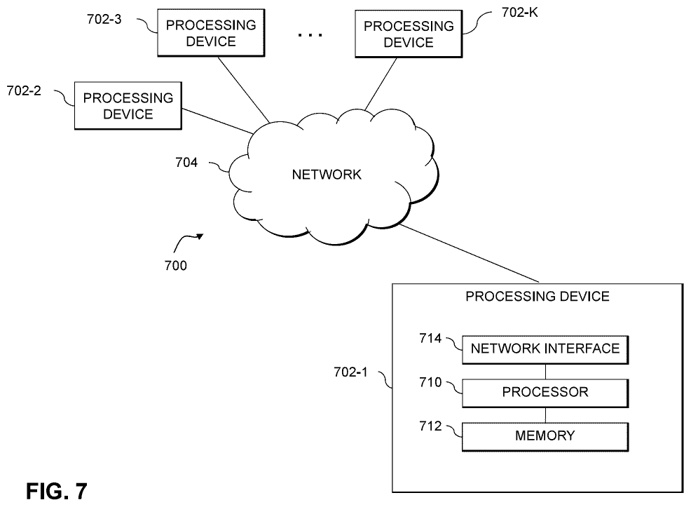

Illustrative embodiments of processing platforms will now be described in greater detail with reference to FIGS. 6 and 7. Although described in the context of the information processing system 100, these platforms may also be used to implement at least portions of other information processing systems in other embodiments.

FIG. 6 shows an example processing platform comprising cloud infrastructure 600. The cloud infrastructure 600 comprises a combination of physical and virtual processing resources that are utilized to implement at least a portion of the information processing system 100. The cloud infrastructure 600 comprises multiple virtual machines (VMs) and/or container sets 602-1, 602-2, . . . 602-L implemented using virtualization infrastructure 604. The virtualization infrastructure 604 runs on physical infrastructure 605, and illustratively comprises one or more hypervisors and/or operating system level virtualization infrastructure. The operating system level virtualization infrastructure illustratively comprises kernel control groups of a Linux operating system or other type of operating system.

The cloud infrastructure 600 further comprises sets of applications 610-1, 610-2, . . . 610-L running on respective ones of the VMs/container sets 602-1, 602-2, . . . 602-L under the control of the virtualization infrastructure 604. The VMs/container sets 602 comprise respective VMs, respective sets of one or more containers, or respective sets of one or more containers running in VMs. In some implementations of the FIG. 6 embodiment, the VMs/container sets 602 comprise respective VMs implemented using virtualization infrastructure 604 that comprises at least one hypervisor.

A hypervisor platform may be used to implement a hypervisor within the virtualization infrastructure 604, where the hypervisor platform has an associated virtual infrastructure management system. The underlying physical machines comprise one or more distributed processing platforms that include one or more storage systems.

In other implementations of the FIG. 6 embodiment, the VMs/container sets 602 comprise respective containers implemented using virtualization infrastructure 604 that provides operating system level virtualization functionality, such as support for Docker containers running on bare metal hosts, or Docker containers running on VMs. The containers are illustratively implemented using respective kernel control groups of the operating system.

As is apparent from the above, one or more of the processing modules or other components of the information processing system 100 may each run on a computer, server, storage device or other processing platform element. A given such element is viewed as an example of what is more generally referred to herein as a “processing device.” The cloud infrastructure 600 shown in FIG. 6 may represent at least a portion of one processing platform. Another example of such a processing platform is processing platform 700 shown in FIG. 7.

The processing platform 700 in this embodiment comprises a portion of the information processing system 100 and includes a plurality of processing devices, denoted 702-1, 702-2, 702-3, . . . 702-K, which communicate with one another over a network 704.

The network 704 comprises any type of network, including by way of example a global computer network such as the Internet, a WAN, a LAN, a satellite network, a telephone or cable network, a cellular network, a wireless network such as a Wi-Fi or WiMAX network, or various portions or combinations of these and other types of networks.

The processing device 702-1 in the processing platform 700 comprises a processor 710 coupled to a memory 712.

The processor 710 comprises a microprocessor, a microcontroller, an application-specific integrated circuit (ASIC), a field-programmable gate array (FPGA) or other type of processing circuitry, as well as portions or combinations of such circuitry elements.

The memory 712 comprises random access memory (RAM), read-only memory (ROM) or other types of memory, in any combination. The memory 712 and other memories disclosed herein should be viewed as illustrative examples of what are more generally referred to as “processor-readable storage media” storing executable program code of one or more software programs.

Articles of manufacture comprising such processor-readable storage media are considered illustrative embodiments. A given such article of manufacture comprises, for example, a storage array, a storage disk or an integrated circuit containing RAM, ROM or other electronic memory, or any of a wide variety of other types of computer program products. The term “article of manufacture” as used herein should be understood to exclude transitory, propagating signals. Numerous other types of computer program products comprising processor-readable storage media can be used.

Also included in the processing device 702-1 is network interface circuitry 714, which is used to interface the processing device with the network 804 and other system components, and may comprise conventional transceivers.

The other processing devices 702 of the processing platform 700 are assumed to be configured in a manner similar to that shown for processing device 702-1 in the figure.

Again, the particular processing platform 700 shown in the figure is presented by way of example only, and the information processing system 100 may include additional or alternative processing platforms, as well as numerous distinct processing platforms in any combination, with each such platform comprising one or more computers, servers, storage devices or other processing devices.

For example, other processing platforms used to implement illustrative embodiments can comprise different types of virtualization infrastructure, in place of or in addition to virtualization infrastructure comprising virtual machines. Such virtualization infrastructure illustratively includes container-based virtualization infrastructure configured to provide Docker containers or other types of LXCs.

As another example, portions of a given processing platform in some embodiments can comprise converged infrastructure.

It should therefore be understood that in other embodiments different arrangements of additional or alternative elements may be used. At least a subset of these elements may be collectively implemented on a common processing platform, or each such element may be implemented on a separate processing platform.

Also, numerous other arrangements of computers, servers, storage products or devices, or other components are possible in the information processing system 100. Such components can communicate with other elements of the information processing system 100 over any type of network or other communication media.

For example, particular types of storage products that can be used in implementing a given storage system of a distributed processing system in an illustrative embodiment include all-flash and hybrid flash storage arrays, scale-out all-flash storage arrays, scale-out NAS clusters, or other types of storage arrays. Combinations of multiple ones of these and other storage products can also be used in implementing a given storage system in an illustrative embodiment.

It should again be emphasized that the above-described embodiments are presented for purposes of illustration only. Many variations and other alternative embodiments may be used. Also, the particular configurations of system and device elements and associated processing operations illustratively shown in the drawings can be varied in other embodiments. Thus, for example, the particular types of processing devices, modules, systems and resources deployed in a given embodiment and their respective configurations may be varied. Moreover, the various assumptions made above in the course of describing the illustrative embodiments should also be viewed as exemplary rather than as requirements or limitations of the disclosure. Numerous other alternative embodiments within the scope of the appended claims will be readily apparent to those skilled in the art.

What is claimed is:

1. A method comprising:
monitoring, by a simulation analysis system, user interactions with User Interface (UI) elements on a user interface to obtain click patterns associated with the UI elements;
generating, by the simulation analysis system, simulated user profiles based on the user interactions;
calculating, by the simulation analysis system, a User Interface/User Experience (UI/UX) impact using the click patterns associated with the simulated user profiles; and
identifying, by the simulation analysis system, a set of high impact UI elements associated with the UI, wherein the method is performed by at least one processing device comprising a processor coupled to a memory.

2. The method of claim 1 wherein monitoring user interactions with the User Interface (UI) elements on the user interface comprises:
capturing clickstream parameters using a website analytics system, wherein the clickstream parameters are associated with the user interactions.

3. The method of claim 2 wherein capturing clickstream parameters comprises:
capturing a click location representing a location in a user interface where a user clicked during a clickstream session; and
capturing a scroll location representing a time value associated with the user clicking on the user interface at the location.

4. The method of claim 3 wherein the website analytics system determines a beginning point and an ending point associated with the clickstream session.

5. The method of claim 3 further comprising:
translating the click location into at least one of a button and a clickable link in the user interface.

6. The method of claim 1 wherein generating simulated user profiles based on the user interactions comprises:
generating a simulated user from a clickstream session.

7. The method of claim 1 wherein generating simulated user profiles based on the user interactions comprises:
creating a user profile associated with a simulated user, wherein the user profile represents at least one of demographics, behavior patterns and user preferences.

8. The method of claim 1 wherein calculating the User Interface/User Experience (UI/UX) impact comprises:
determining a button relative weight using button location data, wherein the button location data represents a location in the user interface where a user clicked during a clickstream session.

9. The method of claim 8 wherein the button relative weight is a sum of clicks associated with the button location data associated with a plurality of clickstream sessions, divided by a sum of clicks associated with a plurality of button location data associated with the plurality of clickstream sessions, wherein each of the plurality of button location data represents a unique location in the user interface where the user clicked during a clickstream session.

10. The method of claim 8 further comprising:
determining a scroll location weight using the button relative weight.

11. The method of claim 10 wherein the scroll location weight is the button relative weight multiplied by a scroll location percent associated with a scroll location, wherein the scroll location percent represents a percentage of users who have scrolled to the scroll location.

12. The method of claim 11 wherein a scroll location heatmap system provides the scroll location percent.

13. The method of claim 1 wherein calculating the User Interface/User Experience (UI/UX) impact comprises:
determining a button depth weight using a button relative weight.

14. The method of claim 13 further comprising:
determining the button depth weight by dividing the button relative weight by prior button clicks representing how many buttons were clicked and how many URL links were clicked before the button associated with the button depth weight was clicked within a clickstream session.

15. The method of claim 1 wherein calculating the User Interface/User Experience (UI/UX) impact comprises:
determining a clickstream summation for each button in a clickstream session by summing a button dept weight and a scroll location weight associated with the each button in the clickstream session.

16. The method of claim 15 further comprising:
determining a button summation across a plurality of clickstream sessions for each button in the plurality of clickstream sessions, wherein the button summation is determined using the clickstream summation.

17. The method of claim 16 further comprising:
calculating a standard deviation of the button summation across the plurality of clickstream sessions for each button in the plurality of clickstream sessions; and
identifying the UI/UX impact for each button in the plurality of clickstream sessions based on the standard deviation.

18. The method of claim 1 wherein identifying the set of high impact UI elements associated with the UI comprises:
in response to selection of one of the UI elements in the UI, providing an impact assessment associated with modifying the one of the UI elements.

19. A system comprising:
at least one processing device comprising a processor coupled to a memory;
the at least one processing device being configured:
to monitor, by a simulation analysis system, user interactions with User Interface (UI) elements on a user interface to obtain click patterns associated with the UI elements;
to generate, by the simulation analysis system, simulated user profiles based on the user interactions;
to calculate, by the simulation analysis system, a User Interface/User Experience (UI/UX) impact using the click patterns associated with the simulated user profiles; and
to identify, by the simulation analysis system, a set of high impact UI elements associated with the UI.

20. A computer program product comprising a non-transitory processor-readable storage medium having stored therein program code of one or more software programs, wherein the program code when executed by at least one processing device causes said at least one processing device:
to monitor, by a simulation analysis system, user interactions with User Interface (UI) elements on a user interface to obtain click patterns associated with the UI elements;
to generate, by the simulation analysis system, simulated user profiles based on the user interactions;
to calculate, by the simulation analysis system, a User Interface/User Experience (UI/UX) impact using the click patterns associated with the simulated user profiles; and
to identify, by the simulation analysis system, a set of high impact UI elements associated with the UI.
